(19) United States
(12) Patent Application Publication
(10) Pub. No.: US 2026/0314484 A1
(43) Pub. Date: Oct. 8, 2026

(54) ELECTRONIC DEVICES AND METHODS OF MANUFACTURING ELECTRONIC DEVICES

(71) Applicant: Amkor Technology Singapore Holding Pte. Ltd., Singapore (SG)

(72) Inventors: Weon Jae Jung, Incheon (KR); Soo Hyun Kim, Incheon (KR); Hee Jun Jang, Daejeon (KR); Su Hwan Bae, Incheon (KR); Seung Uk Yang, Incheon (KR); Tae Kyeong Hwang, Incheon (KR); Won Chul Do, Seoul (KR)

(73) Assignee: Amkor Technology Singapore Holding Pte. Ltd., Singapore (SG)

(21) Appl. No.: 19/169,863

(22) Filed: Apr. 3, 2025

(51) Int. Cl. H01L 25/16; H01L 21/56; H01L 23/00; H01L 23/31; H01L 23/538; H01L 25/00; H01L 25/03; H01L 25/065; H01L 25/07

(52) U.S. Cl. CPC H10W 90/00; H10W 70/611; H10W 74/016; H10W 74/121; H10W 90/401; H10W 72/352; H10W 72/877; H10W 74/15; H10W 76/67; H10W 90/724; H10W 90/734; H10W 90/736

(57) ABSTRACT

In one example, an electronic device can include a substrate, a module comprising an electronic component and coupled to the substrate, and a first passive device coupled to the substrate and disposed adjacent a first side of the module. An underfill can cover the first passive device, and it can be disposed between the first passive device and the substrate. The first passive device can be within 100 μm of the module. The first passive device can be within 50 μm of a fillet of the underfill. A second passive device can be coupled to the substrate and disposed adjacent a second side of the module opposite the first side of the module. The second passive device can be covered by the underfill. The first side of the module comprises a molded sidewall oriented towards the first passive device. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIGS. 1 and 1A show a cross-sectional view of an example electronic device.

FIGS. 2A to 2J show cross-sectional views of an example method for manufacturing an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or describe two elements indirectly coupled by one or more other elements. Unless specified otherwise, the term “coupled” can refer to a mechanical or an electrical coupling.

### DESCRIPTION

An example electronic device can include a substrate, a module comprising an electronic component and coupled to the substrate, and a first passive device coupled to the substrate and disposed adjacent a first side of the module. An underfill can cover the first passive device, can be disposed between the first passive device and the substrate, and can be disposed between the module and the substrate.

In some examples the first passive device is within 100 micrometers (μm) of the module. The first passive device can be within 50 micrometers (μm) of a fillet of the underfill. A second passive device can be coupled to the substrate and disposed adjacent a second side of the module opposite the first side of the module. The second passive device can be covered by the underfill. The first side of the module comprises a molded sidewall oriented towards the first passive device. A thermal interface material (TIM) can be coupled to an upper side of the module, and a lid can be coupled to the TIM. The TIM can include an indium-based material. An adhesive can couple the lid to the substrate. A height of the first passive device above the substrate is greater than a distance between an upper side of the substrate and a lower side of the module.

Another example electronic device comprises a substrate, an electronic component coupled to the substrate, and a first passive device coupled to the substrate and disposed adjacent a first side of the electronic component. An underfill can cover the first passive device, with the underfill disposed between the first passive device and the substrate, and be disposed between the electronic component and the substrate.

An example method of making an electronic device includes the steps of providing a base substrate, providing a module coupled to the base substrate, and providing a passive device coupled to the base substrate and disposed lateral to a sidewall of the module. An underfill can be provided between the base substrate and the module. The underfill can be disposed over the passive device.

Other examples are included in the present disclosure. Such examples may be found in the figures, in the claims, or in the description of the present disclosure.

Various examples of electronic devices and associated methods can include integrated passive devices (IPDs) located in close proximity to a processing die or other electronic components. The short distance between an IPD and the electronic component can improve electronic performance of the resulting electronic device by placing, for example, a capacitor in an ideal or nearly ideal location. The typical keep-out-zone rules sometimes associated with use of polymer resin and IPDs can be avoided in some examples, and resulting devices can include IPDs placed within 100 micrometers (μm) or less of an associated electronic component, electronic module, or electronic device. Performance levels in high-performance computing (HPC) and power delivery networks (PDN) can be improved using such electronic devices and related techniques.

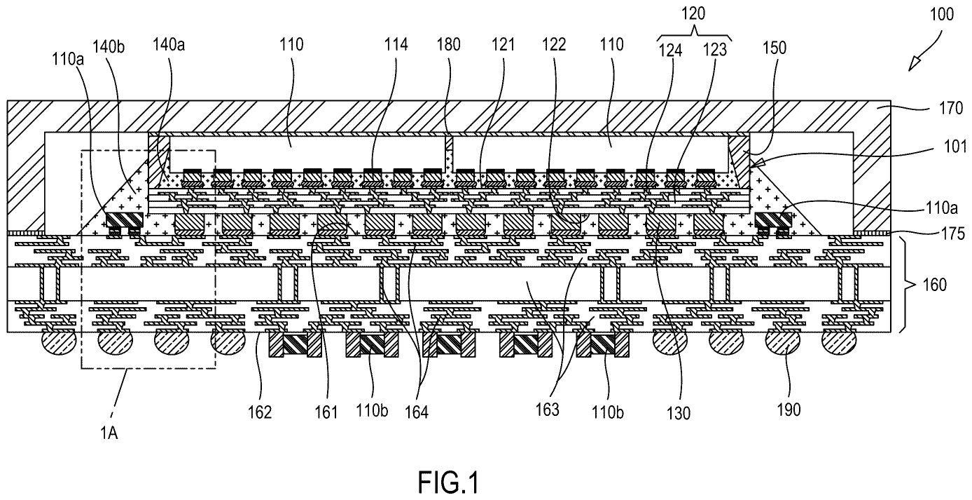

FIG. 1 shows a cross-sectional view of example electronic device 100. FIG. 1A shows a close-up view of the portion of electronic device 100 located in box 1A in FIG. 1. With combined reference to FIGS. 1 and 1A, electronic device 100 can comprise electronic module 101, electronic components 110a, electronic components 110b, underfill 140b, base substrate 160, lid 170, and external interconnects 190. Electronic module 101 of electronic device 100 can comprise electronic components 110, module substrate 120, module connectors 130, underfill 140a, and encapsulant 150.

Module substrate 120 comprises inner side 121, outer side 122, dielectric structure 123, and conductive structure 124. Electronic components 110 can be coupled to inner side 121 of module substrate 120. Connectors 114 can couple electronic components 110 to conductive structure 124.

Base substrate 160 comprises inner side 161, outer side 162, dielectric structure 163, and conductive structure 164. Electronic components 110a and electronic module 101 can be coupled to inner side 161 of base substrate 160. Module connectors 130 can couple electronic module 101 to conductive structure 164. In accordance with various examples, electronic components 110a can be adjacent electronic module 101 (e.g., adjacent a lateral side of module substrate 120) and in underfill 140b. Locating electronic components 110a in underfill 140b can decrease an overall footprint of electronic device 100, reduce a length of the electrical path between electronic components 110a and electronic module 101, and/or allow a greater number of components to be coupled to inner side 161 of base substrate 160.

In some examples, electronic components 110b can be coupled to outer side 162 of base substrate 160. Lid 170 can be coupled to base substrate 160 via a lid adhesive 175. A thermal interface material (TIM) 180 can be coupled between lid 170 and electronic components 110.

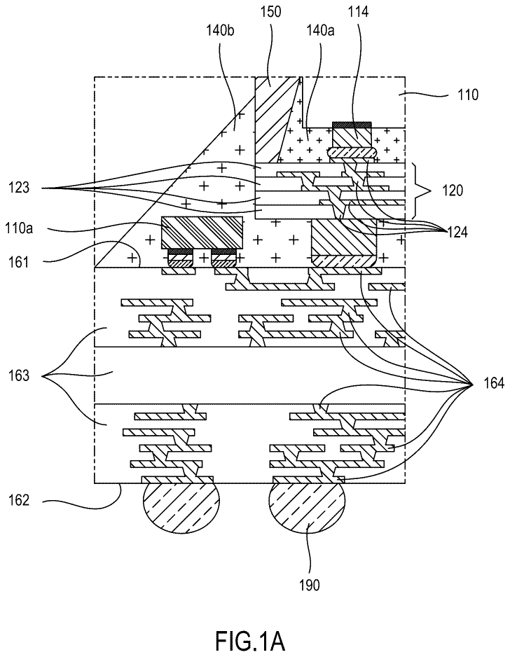

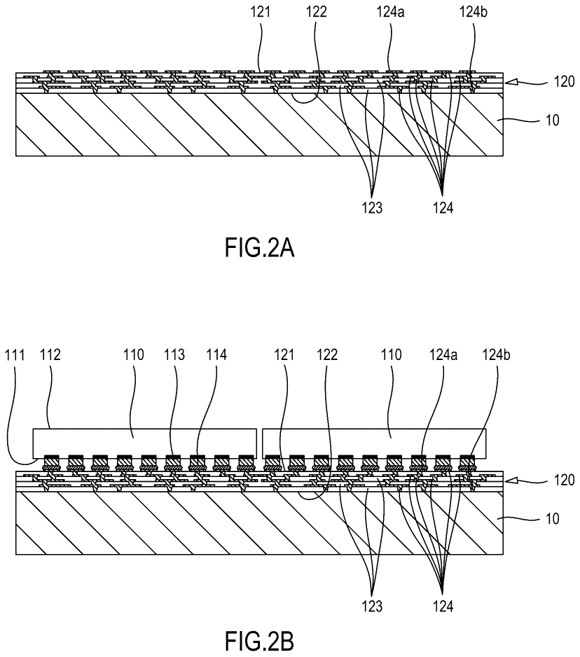

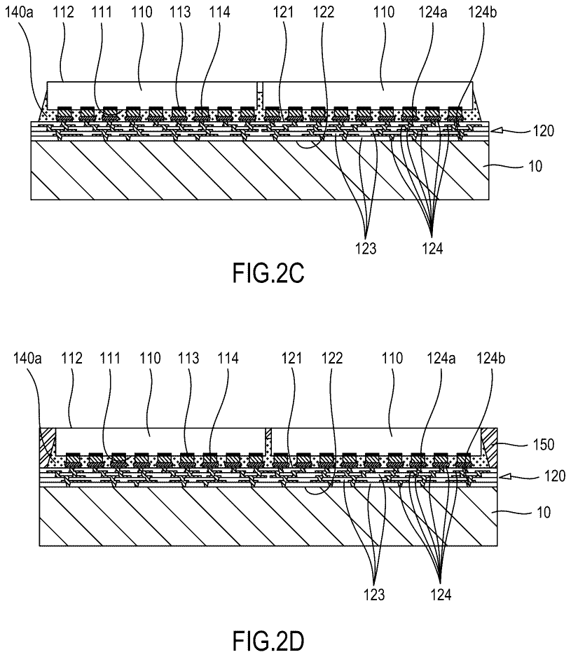

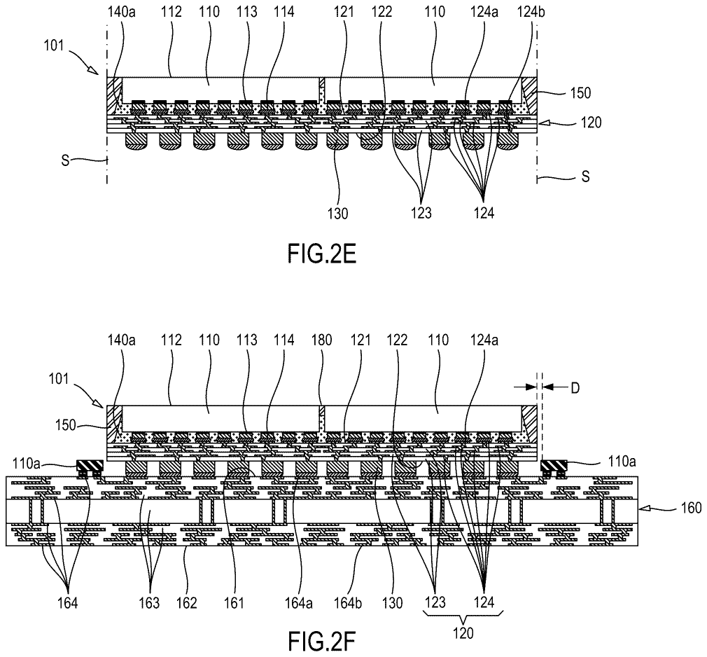

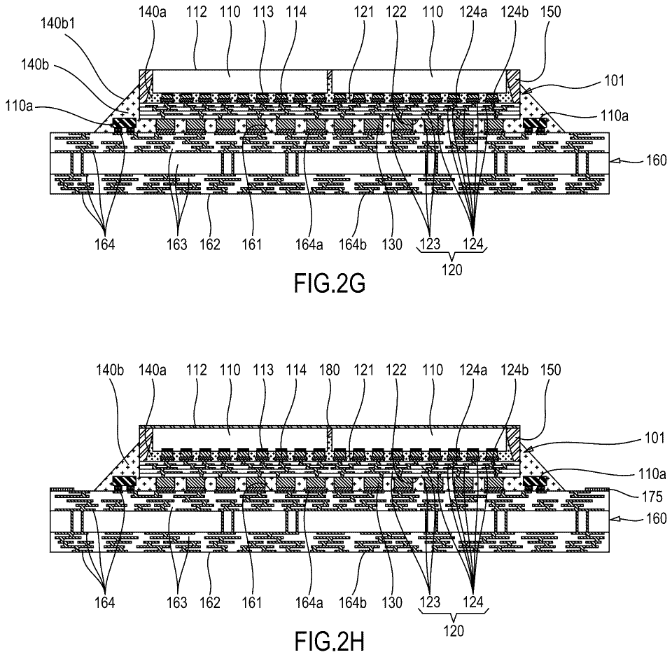

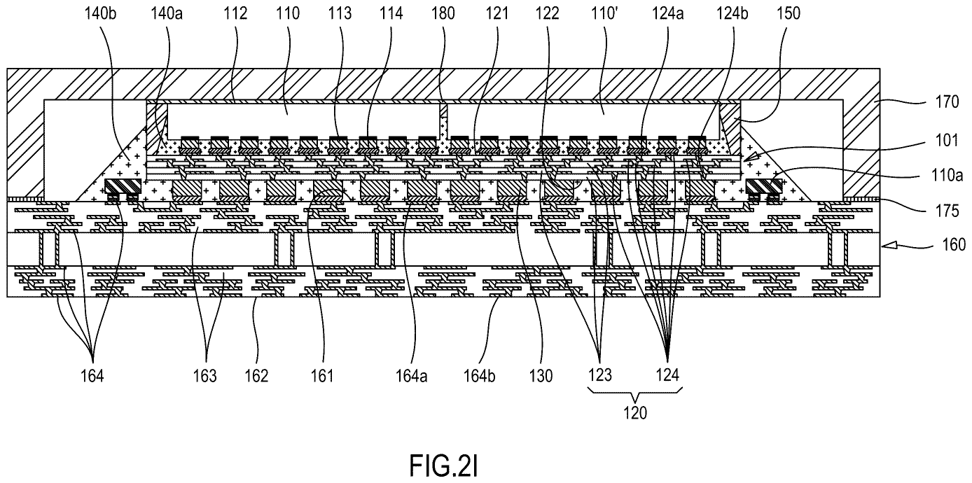

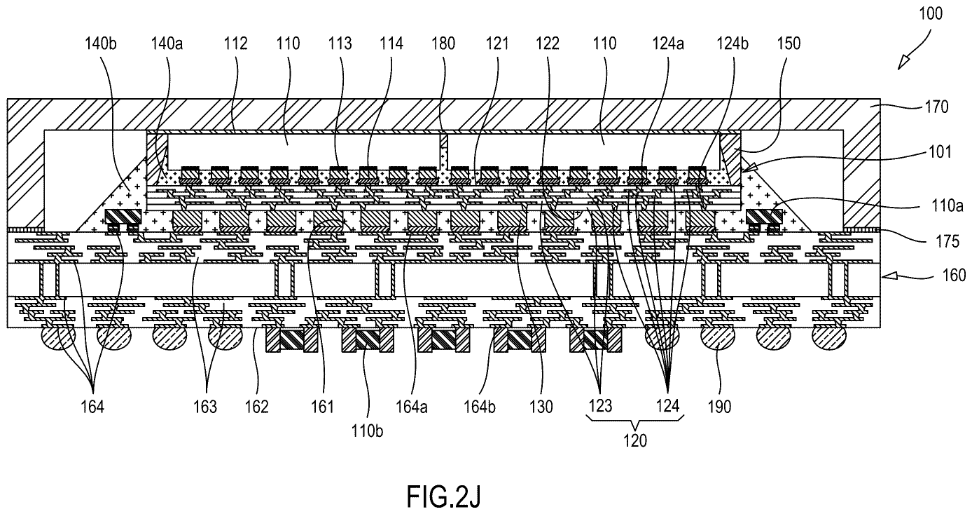

FIGS. 2A to 2J show cross-sectional views of an example method for manufacturing an example electronic device, such as electronic device 100 in FIG. 1.

FIG. 2A shows a cross-sectional view of electronic device 100 at an early stage of manufacture. In the example shown in FIG. 2A, module substrate 120 can be provided on carrier 10. Module substrate 120 can comprise dielectric structure 123 and conductive structure 124. Layers or elements of dielectric structure 123 and conductive structure 124 can be sequentially provided over carrier 10.

Carrier 10 can be a planar support structure having a rectangular, square, or circular shape, when viewed from above. In some examples, carrier 10 can comprise or be referred to as a plate, a board, a wafer, a panel, or a strip. Carrier 10 can be made of, for example, metal, ceramic, glass, or semiconductor or wafer material. In some examples, the thickness of carrier 10 can range from approximately 300 μm to approximately 2000 μm, and the width of carrier 10 can range from approximately 100 millimeters (mm) to approximately 300 mm. In some examples, carrier 10 can have a width of up to 600 mm or greater. As used herein to describe numerical values, the term approximately can mean +/−5%, +/−10%, +/−15%, +/−20%, or +/−25%. Carrier 10 can support the simultaneous (or nearly simultaneous) manufacture of multiple electronic modules 101.

In some examples, carrier 10 can comprise a temporary bond layer provided between the upper side of carrier 10 and outer side 122 of module substrate 120. The temporary bond layer can be referred to as a temporary bonding film, a temporary bonding tape, or a temporary bonding coating. In some examples, the temporary bond layer can be a heat-release tape (or film) or a light-release tape (or film). The temporary bond layer can have its adhesive strength weakened or removed by heat, light, physical force, or chemical force. The temporary bond layer can enable easy separation of module substrate 120 from carrier 10.

Dielectric structure 123 can be provided over carrier 10 using physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), spin coating, spray coating, dip coating, rod coating, or any other suitable deposition process. Dielectric structure 123 can comprise one or more layers of organic dielectric material (e.g., polyimide (PI), benzocyclobutene (BCB), polybenzoxazole (PBO), phenolic resin, or Ajinomoto Buildup Film (ABF)), inorganic dielectric material (e.g., silicon oxide (SiO2), silicon nitride (Si3N4), silicon oxynitride (SiON), tantalum pentoxide (Ta2O5), or aluminum oxide (Al2O3)), or other dielectric material having similar insulating and structural properties. The thickness of individual layers of dielectric structure 123 can range from approximately 1 micrometer (μm) to approximately 10 μm. The combined thickness of the layers of dielectric structure 123 can be substantially equal to or can define the thickness of module substrate 120. Dielectric structure 123 can maintain the shape of module substrate 120 and can also structurally support conductive structure 124. In some examples, the thickness of module substate 120 can range from approximately 10 μm to approximately 80 μm.

Conductive structure 124 can be interleaved with layers or elements of dielectric structure 123. Conductive structure 124 can comprise or be referred to as one or more conductive layers defining signal distribution elements, traces, vias, pads, conductive patterns, conductive paths, wiring patterns, circuit patterns, or under bump metallization (UBM). Conductive structure 124 can be formed using PVD, CVD, electrolytic plating, electroless plating process, or other suitable metal deposition process. Conductive structure 124 can comprise one or more layers of aluminum (Al), titanium (Ti), titanium tungsten (TiW), copper (Cu), tin (Sn), nickel (Ni), gold (Au), silver (Ag), palladium (Pd), or other suitable electrically conductive material.

Conductive structure 124 can comprise inward terminals 124a on inner side 121 of module substrate 120 and outward terminals 124b on outer side 122 of module substrate 120. Outer side 122 of module substate 120 is opposite (e.g., oriented away from) inner side 121 of module substrate. In some examples, inward terminals 124a and/or outward terminals 124b can comprise or be referred to as pads, lands, studs, or UBM.

In some examples, module substrate 120 can be a redistribution layer (“RDL”) substrate. RDL substrates can comprise one or more conductive redistribution layers and one or more dielectric layers and (a) can be formed layer by layer over an electronic device to where the RDL substrate is to be coupled, or (b) can be formed layer by layer over a carrier and can be entirely removed or at least partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process and can include one or more dielectric layers alternatingly stacked with one or more conductive layers that define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process and can include a photolithographic mask through where light is exposed to photo-pattern desired features such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and can interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of inorganic dielectric layer(s) can comprise silicon nitride (Si3N4), silicon oxide (SiO2), and/or SiON. The inorganic dielectric layer(s) can be formed by growing the inorganic dielectric layers using an oxidation or nitridization process instead of using photo-defined organic dielectric materials. Such inorganic dielectric layers can be filler-fee, without strands, weaves, or other dissimilar inorganic particles. In some examples, the RDL substrates can omit a permanent core structure or carrier generally associated with cored laminate substrates. Other substrates in the present disclosure can also comprise an RDL substrate.

In some examples, module substrate 120 can be a pre-formed (or laminate) substrate. The pre-formed/laminate substrate can be manufactured prior to attachment to an electronic device and can comprise dielectric layers between respective conductive layers. The conductive layers can comprise copper and can be formed using an electroplating process. The dielectric layers can be relatively thicker non-photo-definable layers, can be attached as a pre-formed film rather than as a liquid, and can include a resin with fillers such as strands, weaves, and/or other inorganic particles for rigidity and/or structural support. Since the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising BT or FR4, and dielectric and conductive layers can be formed on the permanent core structure. In other examples, the pre-formed substrate can be a coreless substrate omitting the permanent core structure, and the dielectric and conductive layers can be formed on a sacrificial carrier that is removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process. Other substrates in this disclosure can also comprise a pre-formed substrate.

FIG. 2B shows a cross-sectional view of electronic device 100 at a later stage of manufacture. In the example shown in FIG. 2B, electronic components 110 can be provided on inner side 121 of module substrate 120. Electronic components 110 can be coupled to inward terminals 124a of conductive structure 124.

Electronic components 110 can comprise lower side 111 and upper side 112. Upper side 112 of electronic component 110 is opposite lower side 111. In some examples, lower side 111 of electronic component 110 can comprise or be referred to as an active side, and upper side 112 can comprise or be referred to as an inactive side or back side.

Electronic components 110 can comprise contacts 113 on lower side 111. Contacts 113 can be provided in rows and columns along lower side 111. In some examples, contacts 113 can comprise or be referred to as bond pads, contact pads, pads, studs, or pillars. In some examples, contacts 113 can be exposed through a SiO2 film or SiN film located over lower side 111. In some examples, redistribution layers can be between contacts 113 and the active circuity (e.g., transistor region) and/or BEOL components of electronic component 110.

Connectors 114 can couple contacts 113 of electronic component 110 to inward terminals 124a of module substrate 120. In some examples, connectors 114 can comprise or be referred to as bumps, SnPb bumps, leadfree bumps, Cu interconnects, stud bumps, pillars, posts, or solder-capped posts. Connectors 114 can be provided on contacts 113 by, for example, plating, ball-drop, solder reflow, or any other suitable deposition process.

In some examples, pick-and-place equipment can pick up electronic components 110 and place them on inner side 121 of module substrate 120. Connectors 114 of electronic component 110 can be positioned on inward terminals 124a of conductive structure 124. Contacts 113 of electronic component 110 can be electrically coupled to inward terminals 124a through connectors 114 through, for example, a reflow, thermal compression, or laser assisted bonding process of connectors 114 to inward terminals 124a. In some examples, electronic component 110 can comprise or be referred to as a die, a chip, a package (e.g., including multiple die), or a passive component. In some examples, the overall thickness of electronic components 110 can range from approximately 50 μm to approximately 780 μm.

FIG. 2C shows a cross-sectional view of electronic device 100 at a later stage of manufacture. In the example shown in FIG. 2C, underfill 140a can be provided between electronic components 110 and module substrate 120. Underfill 140a can be positioned between lower side 111 of electronic component 110 and inner side 121 of module substrate 120. Underfill 140a can contact lower side 111 of electronic component 110 and inner side 121 of module substrate 120. In some examples, underfill 140a can surround and contact connectors 114.

Underfill 140a can comprise or be referred to as an electrically insulating material and can be free of inorganic fillers. In some examples, underfill 140a can comprise or be referred to as a capillary underfill (CUF), a nonconductive paste (NCP), a nonconductive film (NCF), an anisotropic conductive film (ACF), or an anisotropic conductive paste (ACP). In some examples, underfill 140a can be cured after being provided between electronic components 110 and module substrate 120. Underfill 140a can help reduce occurrences of electronic components 110 being separated from module substrate 120.

FIG. 2D shows a cross-section view of electronic device 100 at a later stage of manufacture. In the example shown in FIG. 2D, encapsulant 150 can be provided over module substrate 120 and electronic components 110. In some examples, encapsulant 150 can contact underfill 140a, upper side 121 of module substrate 120, and the lateral sides of electronic components 110. In some examples, encapsulant 150 can be between upper side 121 of module substrate 120 and electronic components 110. For example, encapsulant 150 can be a molded underfill (MUF) and can replace underfill 140a.

In some examples, encapsulant 150 can comprise or be referred to as a body or mold. Encapsulant 150 can comprise an epoxy mold compound, a resin, an organic polymer with an inorganic filler, a curing agent, a catalyst, a coupling agent, a colorant, or a flame retardant. Encapsulant 150 can be formed by compression molding, transfer molding, liquid body molding, vacuum lamination, paste printing, film-assisted molding, or any other suitable process. In some examples, encapsulant 150 can initially be provided over upper side 112 of electronic components 110, and an upper portion of encapsulant 150 can be removed to expose upper side 112 of electronic components 110. The upper side of encapsulant 150 and upper side 112 of electronic component 110 can be coplanar. Encapsulant 150 can protect electronic components 110 from external factors.

FIG. 2E shows a cross-sectional view of electronic device 100 at a later stage of manufacture. In the example shown in FIG. 2E, carrier 10 is removed, individual electronic modules 101 are singulated from one another, and module connectors 130 are provided on outer side 122 of module substrate 120.

In accordance with various examples, carrier 10 can be removed from module substrate 120. For example, heat, light, a chemical solution, or physical force can be applied to separate carrier 10 from outer side 122 of module substrate 120. Removal of carrier 10 exposes outer side 122 of module substrate 120.

Module connectors 130 can be coupled to outward terminals 124b located on outer side 122 of module substrate 120. Module connectors 130 can be electrically coupled to electronic components 110 through conductive structure 124 of module substrate 120. In some examples, module connectors 130 can comprise Sn, Ag, lead (Pb), Cu, Sn—Pb, Sn37-Pb, Sn95-Pb, Sn—Pb—Ag, Sn—Cu, Sn—Ag, Sn—Au, Sn—Bi, or Sn—Ag—Cu. For example, module connectors 130 can be formed by forming a conductive material including solder on an outward terminals 124b of module substrate 120 through a ball drop process, and then through a reflow process. Module connectors 130 can comprise or be referred to as conductive balls, such as solder balls, conductive pillars, such as copper pillars, or conductive posts having solder caps formed on copper pillars. In some examples, a height of module connectors 130 can range from approximately 65 μm to approximately 80 μm, though other examples of module connectors may comprise lesser or greater heights.

After providing module connectors 130, a singulation process can be performed to provide individual electronic module 101. Singulation can comprise sawing along singulation lines S. For example, electronic modules 101 can be singulated by cutting through encapsulant 150 and module substrate 120. After singulation, the lateral sides of encapsulant 150 can be coplanar with the lateral sides of module substrate 120. Electronic module 101 can comprise electronic components 110, module substrate 120, module connectors 130, and encapsulant 150. In some examples, electronic module 101 can comprise underfill 140a. In some examples, the overall thickness of electronic module 101 can range from approximately 700 μm to approximately 800 μm, from approximately 600 μm to approximately 900 μm, or from approximately 500 μm to approximately 1,000 μm. In some examples, the area or “footprint” of electronic module 101 can range from approximately 1.26 mm×0.505 mm to approximately 1.10 mm×0.606 mm, or from approximately 0.5 mm×0.5 mm to approximately 2 mm×2 mm. In some examples, module dimensions and footprint area can be determined by self-align after reflow.

FIG. 2F shows a cross-sectional view of electronic device 100 at a later stage of manufacture. In the example shown in FIG. 2F, electronic components 110a and electronic module 101 can be provided on inner side 161 of base substrate 160.

In accordance with various examples, base substrate 160 can comprise inner side 161 and outer side 162 opposite to inner side 161. Electronic module 101 and electronic components 110a can be provided over and coupled to inner side 161 of base substrate 160. Outer side 162 of base substrate 160 can be configured for mounting electronic device 100 to external components or boards. For example, as described with reference to FIG. 2J, external interconnects 190 can located on and coupled to outer side 162 of base substrate 160.

Base substrate 160 can comprise dielectric structure 163 and conductive structure 164. In some examples, dielectric structure 163 can comprise or be referred to as one or more stacked dielectric layers. For instance, the one or more dielectric layers can comprise, one or more core layers, polymer layers, pre-preg layers, Ajinomoto Buildup Film (ABF) layer, or solder mask layers stacked on each other. One or more layers or elements of conductive structure 164 can be interleaved with elements or layers of dielectric structure 163. In some examples, dielectric structure 163 can comprise FR4 (copper foil/glass fiber fabric/copper foil laminate), bismaleimide triazine (BT), polyimide (PI), benzocyclobutene (BCB), polybenzoxazole (PBO), phenolic resin, or ABF, mold compound, or glass. The thickness of individual layers of dielectric structure 163 can range from approximately 20 μm to approximately 1400 μm. In some examples, a core of dielectric structure 163 can have thickness of between approximately 100 μm and approximately 1400 μm, between approximately 200 μm and 1250 μm, between approximately 400 μm and 800 μm, of approximately 200 μm, of approximately 820 μm, or of approximately 1250 μm. In some examples, individual layers of dielectric structure 163 (e.g., ABF or prepreg layers) can be laminated to the core structure and/or to one another. The laminated layers of dielectric structure 163 can each have a thickness between approximately 10 μm and approximately 50 μm, between approximately 25 μm and approximately 40 μm, between approximately 25 μm and approximately 35 μm, of approximately 20 μm, of approximately 25 μm, or of approximately 33 μm. In some examples, the outermost dielectric layer on each side of base substrate 160 can comprise a solder mask material, which in some examples, can be different from the material of the laminated layers and/or the material of the core. In some examples, the solder mask (or solder resist) layers can be provided by screen printing and can have a thickness of between approximately 10 μm and approximately 50 μm, between approximately 20 μm and approximately 40 μm, between approximately 20 μm and approximately 30 μm, of approximately 20 μm, or of approximately 22 μm. In some examples, the thickness of the solder mask layer can be less than the thickness of the individual laminated layer(s). The combined thickness of the layers of dielectric structure 163 can define the thickness of base substrate 160. Dielectric structure 163 can maintain the shape of base substrate 160 and can structurally support conductive structure 164.

Conductive structure 164 can comprise or be referred to as one or more conductive layers defining signal distribution elements, traces, vias, pads, under bump metallization (UBM), redistribution layers (RDLs), conductive patterns, conductive paths, wiring patterns, or circuit patterns. In some examples, conductive structure 164 can comprise one or more layers of copper (Cu), aluminum (Al), tin (Sn), titanium (Ti), titanium tungsten (TiW), gold (Au), silver (Ag), nickel (Ni), palladium (Pd), or combinations or alloys thereof. The thickness of conductive structure 164 can be from approximately 5 μm to approximately 50 μm, 10 μm to approximately 30 μm, 15 μm to approximately 25 μm, or 18 μm to approximately 20 μm. The thickness of conductive structure 164 can refer to individual layers of conductive structure 164. In some examples, conductive structure 164 can have a trace width and trace spacing (width/spacing) of between approximately 5 μm/5 μm and approximately 50 μm/50 μm, between approximately 8 μm/8 μm and approximately 40 μm/40 μm, between approximately 9 μm/12 μm and approximately 25 μm/25 μm, or between approximately 9 μm/12 μm and approximately 20 μm/20 μm. Trace width is the width of individual traces of conductive structure 164 and trace spacing is the distance between adjacent traces of conductive structure 164. Conductive structure 164 provides electrical signal paths (e.g., vertical paths and horizontal paths) through dielectric structure 163. Conductive structure 164 can be formed using, for example, sputtering, electroless plating, electroplating physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD). Some portions of conductive structure 164 can be exposed from dielectric structure 163 (e.g., solder mask) at the inner side 161 of base substrate 160 as inward terminals 164a and at outer side 162 of base substrate 160 as outward terminals 164b. In some examples, substrate inward terminals 164a and substrate outward terminals 164b can comprise or be referred to as pads, lands, or UBM. Layers and elements of conductive structure 164 can electrically couple substrate inward terminals 164a with substrate outward terminals 164b.

Base substrate 160 can comprise a core or be coreless. In some examples, base substrate 160 can comprise or be referred to as pre-formed or laminate substrate, as previously described. In some examples, base substrate 160 can comprise or be referred to as a build-up or RDL substate, as previously described. In some examples, an area of base substrate 160 can be adjusted or selected according to the area or number of electronic modules 101 and electronic components 110 a coupled thereto. In some examples, base substate 160 can have an area of approximately 1 mm by 1 mm to approximately 150 mm by 150 mm. Base substrate 160 can have a thickness of approximately 0.2 mm to approximately 4 mm.

Electronic module 101 can be picked up by pick-and-place equipment and placed on inner side 161 of base substrate 160. Module connectors 130 can be located on and then coupled to substrate inward terminals 164a through a reflow, thermal compression, laser assisted, or other bonding process. Electronic components 110 of electronic module 101 can be electrically coupled to conductive structure 164 via substrate inward terminals 164a and module connectors 130.

Electronic components 110a can be coupled to substrate inward terminals 164a of base substrate 160. Electronic components 110a can be electrically coupled to electronic module 101 through conductive structure 164 of base substrate 160. For example, electronic components 110a can be electrically coupled to electronic components 110 through base substrate 160, module connectors 130, and conductive structure 124 of module substrate 120. Electronic components 110a can be positioned in an edge region of electronic module 101. For example, electronic components 110a can be positioned so as to be spaced apart from the sidewall of electronic module 101 by a distance D. In some examples, distance D between the sidewall of electronic component 110 a and the sidewall of electronic module 101 can range from approximately 60 μm to approximately 110 μm. In some examples, the thickness of electronic component 110a can range from approximately 100 μm to approximately 200 μm. In some examples, distance D between the sidewall of electronic component 110 and the sidewall of electronic module 101 can be less than approximately 100 μm. A shorter distance D between electronic component 110a and electronic module 101 can improve electronic performance by reducing the length of the electrical path between electronic component 110a and electronic module 101.

In some examples, electronic component 110a can comprise or be referred to as a passive device, integrated passive device, power device, or intelligent power device. In some examples, electronic component 110a can comprise a capacitor. In some examples, electronic component 110a can comprise or be referred to as a die or a chip. Electronic component 110a can be arranged adjacent to electronic module 101 to improve power supply delivered to electronic components 110. Decreasing the distance between electronic components 110 and electronic components 110a can improve power efficiency of electronic device 100. Electronic device 100 can also exhibit high-performance computing (HPC) performance due to the improved power delivery network (PDN).

Electronic component 110a being disposed in a location adjacent electronic module 101 within distance D can also increase available space on inner side 161 of base substrate 160 outside of electronic components 110a. Additional space on inner side 161 can enable installation of additional electronic components or can reduce an overall footprint of base substrate 160 and electronic device 100.

FIG. 2G shows a cross-sectional view of electronic device 100 at a later stage of manufacture. In the example shown in FIG. 2G, underfill 140b can be provided between module substrate 120 and base substrate 160. In accordance with various examples, underfill 140b can cover electronic components 110a (e.g., electronic components 110a can be in underfill 140b). Underfill 140b can contact outer side 122 of module substrate 120, inner side 161 of base substrate 160, electronic components 110a, and module connectors 130. For example, underfill 140b can contact the sidewall of module substrate 120 and the sidewall of encapsulant 150. A fillet 140b1 of underfill 140b can extend from the sidewall of module 101 to base substrate 160. Fillet 140b1 can be disposed over electronic component 110a. In some examples, an upper side of electronic component 110 a can be disposed within approximately 30 μm, approximately 40 μm, approximately 50 μm, approximately 60 μm, or approximately 70 μm of fillet 140 b1. Underfill 140b can completely cover electronic component 110a in some examples.

In some examples, underfill 140b can be provided between module substrate 120 and base substrate 160, and underfill 140b can cover electronic component 110a leaving an unfilled void in a volume between electronic component 110a and base substrate 160. In some examples, underfill 140b can be provided between module substrate 120 and base substrate 160 and between electronic component 110a and base substrate 160. In some examples, underfill 140b can completely fill or substantially fill the volume between electronic component 110a and base substrate 160.

Underfill 140b can comprise or be referred to as an insulating layer and can be free of inorganic fillers. In some examples, the elements, features, materials, or manufacturing methods of underfill 140b can be similar to or the same as those described above for underfill 140a. The thickness of underfill 140 a over electronic component 110 a can range from approximately 5 μm to approximately 80 μm. Underfill 140 b can reduce occurrences of electronic components 110 a or electronic module 101 separating from base substrate 160.

FIG. 2H shows a cross-sectional view of electronic device 100 at a later stage of manufacture. In the example shown in FIG. 2H, thermal interface material (TIM) 180 can be provided on electronic components 110 and encapsulant 150. TIM 180 can be provided on upper side 112 of electronic components 110 and the upper side of encapsulant 150. In some examples, a metal layer can be interposed between TIM 180 and upper side 112 of electronic components 110 to increase the bonding strength between TIM 180 and electronic components 110. In some examples, the metal layer can comprise or be referred to as a backside metallization (BSM) plating layer, a conductive film, or a conductive membrane. For example, the metal layer can be provided by electrolytic plating, electroless plating, sputtering, or PVD. In some examples, the metal layer can be made of Au or Ag. In some examples, the thickness of the metal layer can range from approximately 0.3 μm to approximately 3 μm.

In some examples, TIM 180 can be a metallic TIM. For example, TIM 180 can comprise a metallic material such as solder, solder paste, gallium, a gallium alloy (e.g., an alloy with indium, tin, or zinc), a silver alloy, tin-silver, indium, and an indium alloy. In some examples, TIM 180 can comprise a polymer TIM. TIM 180 facilitates the transfer or conduction of heat generated from electronic components 110 to lid 170 (FIG. 2I). In some examples, the thickness of TIM 180 can range from approximately 0.1 μm to approximately 200 μm.

Lid adhesive 175 can be provided on inner side 161 of base substrate 160. Lid adhesive 175 can be provided in a ring shape surrounding a perimeter of base substrate 160. In some examples, lid adhesive 175 can comprise or be referred to as a polymer or a dielectric. In some examples, lid adhesive 175 can comprise a thermal adhesive or a non-thermal adhesive. In some examples, the thickness of lid adhesive 175 can range from approximately 5 μm to approximately 300 μm.

FIG. 2I shows a cross-sectional view of electronic device 100 at a later stage of manufacture. In the example shown in FIG. 2I, lid 170 can be provided over electronic module 101 and on inner side 121 of base substrate 160.

Lid 170 can comprise a top plate and sidewalls extending downward from the top plate. In some examples, the top plate and the sidewalls can be integral to one another (e.g., a one-piece lid). In other examples, the top plate can be discrete from and bonded to the sidewalls (e.g., a two-piece lid). In some examples, the top plate of lid 170 can have a trench, protrusions, or fins provided on the top side to improve heat dissipation efficiency.

Electronic components 110a and electronic module 101 can be positioned in lid 170 (e.g., in a cavity defined by the interior sides of the top plate and sidewalls). Lid 170 can surround electronic components 110a and electronic module 101. In some examples, the interior side of the top plate of lid 170 can contact TIM 180. The sidewalls of lid 170 can be coupled to base substrate 160 via lid adhesive 175. After lid 170 is seated on TIM 180 and lid adhesive 175, TIM 180 and/or lid adhesive 175 can be cured through a curing process by using heat, light, ultraviolet rays, or laser.

In some examples, the thickness of the top plate and sidewalls of lid 170 can range from approximately 0.1 mm to approximately 5 mm. In some examples, the height of the sidewalls of lid 170 can range from approximately 0.2 mm to approximately 2 mm. In some examples, lid 170 can comprise or be referred to as a metal lid. For example, lid 170 can be formed of a metal or alloy (e.g., aluminum, nickel, copper, or alloys or combinations thereof). In some examples, lid 170 can be referred to as or comprise a heat sink, a cap cover, an encapsulation, a protection, a package, or a body. Lid 170 can protect electronic components 110a and electronic module 101 from external elements and allow heat generated from electronic components 110 to be quickly and easily dissipated.

FIG. 2J shows a cross-sectional view of electronic device 100 at a later stage of manufacture. In the example shown in FIG. 2J, external interconnects 190 can be provided on outer side 162 of base substrate 160.

External interconnects 190 can contact and be coupled to substrate outward terminals 164b. External interconnects 190 can be electrically coupled to electronic components 110 and 110a through conductive structure 164 of base substrate 160. In some examples, external interconnects 190 can comprise tin (Sn), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. For example, external interconnects 190 can be formed by forming a conductive material including solder on substrate outward terminals 164b through a ball drop process, followed by a reflow process. External interconnects 190 can comprise or be referred to as conductive balls, such as solder balls, conductive pillars, such as copper pillars, or conductive posts having solder caps formed on copper pillars. In some examples, the sizes of external interconnects 190 can range from approximately 100 μm to approximately 1000 μm.

In some examples, external interconnects 190 can be referred to as external input/output terminals of electronic device 100. In some examples, electronic device 100 can be a land grid array (LGA) with substrate outward terminals 164b serving as external input/output terminals (e.g., electronic device 100 can be devoid of external interconnects 190).

In some examples, one or more electronic components 110b can be provided on outer side 162 of base substrate 160. Electronic components 110b can contact and be coupled to substrate outward terminals 164b of conductive structure 164. Electronic components 110b can have corresponding elements, features, materials, or manufacturing methods similar to those of electronic component 110. In some examples, electronic component 110b can comprise or be referred to as a die, a chip, a package, or a passive component. Electronic component 110b can be electrically coupled to electronic module 101, electronic components 110a, and/or external interconnects 190 through conductive structure 164 of base substrate 160.

In some examples, after providing external interconnects 190, a singulation process can be performed by sawing base substrate 160 to separate it into individual electronic devices 100. In some examples, base substrate 160 can be singulated (e.g., provided as discrete substrate units) prior to attaching electronic module 101.

Various examples of electronic devices and associated techniques can reduce the length of the electrical path between adjacent electronic components. For example, an IPD can be placed within extremely close distances of an adjacent semiconductor die, in a region typically maintained as a keep-out zone in some electronic devices. Close proximity between adjacent electronic components can improve electronic performance relative to devices constructed with a more traditional distance between adjacent electronic components.

The present disclosure includes reference to certain examples, however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

1. An electronic device, comprising:
a substrate;
a module comprising an electronic component and coupled to the substrate;
a first passive device coupled to the substrate and disposed adjacent a first side of the module; and
an underfill covering the first passive device, disposed between the first passive device and the substrate, and disposed between the module and the substrate.

2. The electronic device of claim 1, wherein the first passive device is within 100 micrometers (μm) of the module.

3. The electronic device of claim 1, wherein the first passive device is within 50 micrometers (μm) of a fillet of the underfill.

4. The electronic device of claim 1, further comprising a second passive device coupled to the substrate and disposed adjacent a second side of the module opposite the first side of the module.

5. The electronic device of claim 4, wherein the second passive device is covered by the underfill.

6. The electronic device of claim 1, wherein the first side of the module comprises a molded sidewall oriented towards the first passive device.

7. The electronic device of claim 1, further comprising:
a thermal interface material (TIM) coupled to an upper side of the module; and
a lid coupled to the TIM.

8. The electronic device of claim 7, wherein the TIM comprises an indium-based material.

9. The electronic device of claim 7, further comprising an adhesive coupling the lid to the substrate.

10. The electronic device of claim 1, wherein a height of the first passive device above the substrate is greater than a distance between an upper side of the substrate and a lower side of the module.

11. An electronic device, comprising:
a substrate;
an electronic component coupled to the substrate;
a first passive device coupled to the substrate and disposed adjacent a first side of the electronic component; and
an underfill covering the first passive device, disposed between the first passive device and the substrate, and disposed between the electronic component and the substrate.

12. The electronic device of claim 11, wherein a distance between the first passive device and the electronic component is less than 100 micrometers (μm).

13. The electronic device of claim 11, wherein the first passive device is within 50 micrometers (μm) of a fillet of the underfill.

14. A method of making an electronic device, comprising:
providing a base substrate;
providing a module coupled to the base substrate;
providing a passive device coupled to the base substrate and disposed lateral to a sidewall of the module; and
providing an underfill between the base substrate and the module, wherein the underfill is disposed over the passive device.

15. The method of claim 14, wherein a distance between the passive device and the module is less than 100 micrometers (μm).

16. The method of claim 14, wherein a distance between the passive device and the module is in a range from approximately 60 micrometers (μm) to approximately 110 μm.

17. The method of claim 14, further comprising:
providing a thermal interface material (TIM) coupled to an upper side of the module; and
providing a lid coupled to the TIM.

18. The method of claim 14, wherein providing the module comprises:
providing a module substrate;
providing an electronic component coupled to the module substrate; and
providing an encapsulant over the module substrate and coupled to sidewalls of the electronic component.

19. The method of claim 18, further comprising providing a second underfill between the module substrate and the electronic component.

20. The method of claim 14, further comprising providing a second passive device coupled to the base substrate and disposed lateral to a second sidewall of the module.
